(19) United States
(12) Patent Application Publication
(10) Pub. No.: US 2009/0045485 A1
(43) Pub. Date: Feb. 19, 2009

(54) CAPACITOR, METHOD OF MANUFACTURING CAPACITOR, CAPACITOR MANUFACTURING APPARATUS, AND SEMICONDUCTOR MEMORY DEVICE

(75) Inventor: Toshiyuki HIROTA, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/188,307

(22) Filed: Aug. 8, 2008

(30) Foreign Application Priority Data
Aug. 14, 2007 (JP) 2007-211535

(51) Int. Cl. H01L 27/13; C23C 14/34; H01L 21/20

(52) U.S. Cl. 257/532; 204/298.07; 204/192.22; 438/386; 257/E27.113; 257/E21.09

(57) ABSTRACT

The present invention provides a capacitor including: an under electrode; an upper electrode; and a dielectric film which is provided between the under electrode and the upper electrode, wherein at least a portion of the dielectric film is composed of an aluminum oxide film deposited by an atomic layer deposition method and a titanium oxide film deposited by the atomic layer deposition method. An aluminum composition ratio x and a titanium composition ratio y in the dielectric film preferably comply with 7≦[x/(x+y)]×100≦35.

### BACKGROUND OF THE INVENTION

1. Field of the Invention

The present invention relates to a capacitor, method of manufacturing the capacitor, a capacitor manufacturing apparatus, and a semiconductor memory device, especially to improvements of a dielectric film and the method of manufacturing the dielectric film.

Priority is claimed on Japanese Patent Application No. 2007-211535, filed Aug. 14, 2007, the content of which is incorporated herein by reference.

2. Description of Related Art

A cell which is included in a dynamic random access memory (DRAM) includes one transistor and one capacitor. Among those, the capacitor includes an under electrode, a dielectric film and an under electrode. With decreasing the size of the DRAM, the space necessary for the DRAM becomes small. In order to obtain a predetermined value of capacitance with the limitation of the space necessary for the DRAM, the employment of a three dimensional electrode structure and a dielectric film having a high relative dielectric permittivity has been examined.

With regard to the dielectric film, for example, an aluminum oxide (Al₂O₃) film has a relative dielectric permittivity of approximately 9. The aluminum oxide film can suppress a leakage current as compared with a previously employed silicon nitride film having a relative dielectric permittivity of 7, and a stacking structure made from silicon oxide film/silicon nitride film, in which a surface of the silicon nitride film is oxidized, having a relative dielectric permittivity of 3.9, for a same equivalent oxide film thickness (EOT). For this reason, the aluminum oxide film has recently been frequently employed as the dielectric film of the capacitor in the DRAM.

With further decreasing the size of the DRAM, however, the aluminum oxide with the relative dielectric permittivity of 9 becomes insufficient for the dielectric film of the capacitor in the DRAM. Therefore, recently, at a minimum process dimension of 70 nm, a stacking film that includes HfO₂, Al₂O₃ and the like has been examined as the dielectric film of the capacitor. However, when these films are assumed to be amorphous, the effective-relative-dielectric-permittivity is limited at about 20. Moreover, according to the dielectric film, there are some approaches in which the crystallization temperature of yttrium (Y) doped HfO₂ decreases so that the relative dielectric permittivity enhances up to about 40, and crystallized ZrO₂ having a relative dielectric permittivity of about 40 is employed as the dielectric film. Nevertheless, in the crystallized dielectric films, there tends to be an increase of the leakage current as compared with an amorphous state which is a problem.

Furthermore, a SrTiO₃ (STO) film which is categorized in a perovskite structure is discussed and developed as a high relative dielectric permittivity film, though there is no applicable precursor having a high vapor pressure for a strontium source material which is used during a film deposition so far. For this reason, although the SrTiO₃ film deposition is possible in a laboratory, manufacturing technology with a high precision that can be applied to mass production has not yet been established.

Alternately, a titanium oxide (TiO₂) film having a relative dielectric permittivity of about 90 is partially discussed since the relative good titanium (Ti) precursor is available. However, due to a narrow bandgap of the TiO₂ likewise to the SrTiO₃, there is a problem of a large leakage current.

Moreover, in order to obtain stacking structures shown in FIG. 8 through FIG. 10, the dielectric film which includes the titanium oxide (TiO₂) film deposited by an atomic layer deposition (ALD) method and the aluminum oxide (Al₂O₃) film deposited by the atomic layer deposition method has been examined.

For example, according to the stacking structure shown in FIG. 8, between an under electrode 701 and an upper electrode 704, the dielectric film includes an aluminum oxide film 702; and a titanium oxide film 703. The dielectric film is deposited according to the film deposition sequence shown in FIG. 11.

As shown in FIG. 11, initially, a nitrogen purge process is performed for a surface of the under electrode 701 (step 302). Then, an aluminum precursor gas is supplied to a reaction chamber. Aluminum which is generated from the aluminum precursor gas through a chemical reaction is deposited on a deposition plane so that an aluminum film (having a layer thickness of approximately 1 monolayer) is obtained (step 303). After that, the aluminum precursor gas is exhausted from the reaction chamber and the nitrogen purge process is performed (step 304). Subsequently, an oxidization gas is supplied to the reaction chamber. Then, the aluminum film is converted into the aluminum oxide film by oxidizing the aluminum film (step 305). Then, the oxidization gas is exhausted from the reaction chamber and the nitrogen purge process is performed (step 306).

These processes 303 through 306 repeat (H times) until the aluminum oxide film is deposited and reaches a predetermined layer thickness. Thereby, the aluminum oxide film 702 is provided (step 312).

Next, a titanium precursor gas is supplied to a reaction chamber. Titanium which is generated from the titanium precursor gas through a chemical reaction is deposited on the aluminum oxide film 702 so that a titanium film (having a layer thickness of approximately 1 monolayer) is obtained (step 307). After that, the titanium precursor gas is exhausted from the reaction chamber and the nitrogen purge process is performed (step 308). Subsequently, the oxidization gas is supplied to the reaction chamber. Then, the titanium film is converted into the titanium oxide film by oxidizing the titanium film (step 309). After that, the oxidization gas is exhausted from the reaction chamber and the nitrogen purge process is performed (step 310).

These processes 307 through 310 repeat (I times) until the titanium oxide film is deposited and reaches the predetermined layer thickness. Thereby, the titanium oxide film 703 is provided (step 313).

The dielectric film which includes the aluminum oxide film 702 and the titanium oxide film 703 is obtained through the above described processes.

Alternately, according to the stacking structure shown in FIG. 9, the dielectric film having a stacking structure that includes: an aluminum oxide film 802; a titanium oxide film 803; and an aluminum oxide film 804, is provided between an under electrode 801 and an upper electrode 805. The dielectric film is deposited according to the film deposition sequence shown in FIG. 12.

As shown in FIG. 12, initially, the nitrogen purge process is performed for the surface of the under electrode 801 (step 402). The same sequence (steps 403 through 406) of the above described processes (steps 303 through 306) repeats (J times) until the aluminum oxide film is deposited and reaches the predetermined layer thickness. Thereby, the aluminum oxide film 802 is provided (step 416).

Then, the same sequence (steps 407 through 410) of the above described processes (steps 307 through 310) repeats (K times) until the titanium oxide film is deposited and reaches the predetermined layer thickness. Thereby, the titanium oxide film 803 is provided (step 417).

Subsequently, the same sequence (steps 411 through 414) of the above described processes (steps 303 through 306) repeats again (L times) until the aluminum oxide film is deposited and reaches the predetermined layer thickness. Thereby, the aluminum oxide film 804 is provided (step 418).

The dielectric film having the stacking structure that includes: the aluminum oxide film 802; the titanium oxide film 803; and the aluminum oxide film 804, is obtained through the above described processes.

Alternately, according to the stacking structure shown in FIG. 10, the dielectric film having a stacking structure that includes: a titanium oxide film 902; an aluminum oxide film 903; and a titanium oxide film 904, is provided between an under electrode 901 and an upper electrode 905.

In order to deposit the dielectric film, initially, the nitrogen purge process is performed for the surface of the under electrode 901, and the same sequence of the above described processes (steps 307 through 310) repeats. Thereby, the titanium oxide film 902 is provided. Then, the same sequence of the above described processes (steps 303 through 306) repeats. Thereby, the aluminum oxide film 903 is provided. Subsequently, the same sequence of the above described processes (steps 307 through 310) repeats again. Thereby, the titanium oxide film 904 is provided.

For alternative technologies, the dielectric film having a multiple stacking structure which is alternately stacked by the aluminum oxide films and the titanium oxide films is proposed for the capacitor which is employed in semiconductor devices (refer to Japanese Unexamined Patent Application, First Publication, No. 2001-160557).

Furthermore, a dielectric film in which the aluminum oxide film deposited on a film including a tantalum oxide film and the titanium oxide film is known and used for the capacitor (refer to Japanese Unexamined Patent Application, First Publication, No. 2001-237401).

### SUMMARY

According to the dielectric film having the stacking structures shown in FIG. 8 through FIG. 10, however, when the relative dielectric permittivity and the leakage current are investigated, it is revealed that an enhancement of the relative dielectric permittivity conflicts with a decrease in the leakage current so as to result in an insufficient capacitance. In particular, when an application of the dielectric film to the capacitor and the like is considered for future development goals in which the minimum processing dimension of the DRAM is further decreased to 60-nm or 45-nm levels, the conventional capacitor structure is deficient in performance.

The present invention seeks to solve one or more of the above problems, or to improve those problems at least in part.

In one embodiment, there is provided a capacitor that includes an under electrode, an upper electrode, and a dielectric film which is provided between the under electrode and the upper electrode, a portion of the dielectric film including a composite oxide film in which a plurality of aluminum oxide films and a plurality of titanium oxide films are provided in a thickness direction thereof.

According to the constitution, it is possible to obtain a capacitor that has a high relative dielectric permittivity and a low leakage current. For this reason, the capacitor makes it possible obtain a large capacitance even if there is a decrease in the minimum processing dimension of the DRAM.

In one embodiment, there is provided a method of manufacturing the above capacitor comprising depositing the aluminum oxide film and the titanium oxide film by an atomic layer deposition method, and alternately repeating the deposition of the aluminum oxide film and the titanium oxide film to form the composite oxide film.

In one embodiment, there is provided a capacitor manufacturing apparatus for manufacturing the above capacitor, including: a reaction chamber; a gas supply portion that separately supplies an aluminum precursor gas, a titanium precursor gas and an oxidization gas to the reaction chamber; a gas exhaust portion that exhausts the gases from the reaction chamber; and a control portion that controls supply of the gases in the gas supply portion and exhaust of the gases from the gas exhaust portion such that the control portion repeats the atomic layer deposition method by a first cycle number and a second cycle number to obtain a designed aluminum composition ratio and a designed titanium composition ratio, based on predetermined relationships between the aluminum composition ratio and the first cycle number, and between the titanium composition ratio and the second cycle number.

According to the constitution, the aluminum composition ratio and the titanium composition ratio of the composite oxide film can be precisely controlled. Therefore, it is easy to obtain the dielectric film having a designed effective-relative-dielectric-permittivity and a low leakage current.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view that shows a capacitor according to a first embodiment of the present invention;

FIG. 2 is a flow chart that shows a depositing sequence of a dielectric film in a manufacturing method of a capacitor according to the first embodiment;

FIG. 3 is a schematic diagram that shows an example of a capacitor manufacturing apparatus;

FIG. 4 is a cross-sectional view that shows a capacitor according to a second embodiment of the present invention;

FIG. 5 is a flow chart that shows a depositing sequence of a dielectric film in a manufacturing method of a capacitor according to the second embodiment;

FIG. 6 is a cross-sectional view that shows a semiconductor memory device employing the capacitor of the present invention;

FIG. 7 is a graph that shows a leakage current density as a function of an equivalent oxide film thickness (EOT) of a dielectric film according to a semiconductor memory device provided through the embodiments;

FIG. 8 is a cross-sectional view that shows a first example of a capacitor of a related art;

FIG. 9 is a cross-sectional view that shows a second example of a capacitor of the related art;

FIG. 10 is a cross-sectional view that shows a third example of a capacitor of the related art;

FIG. 11 is a flow chart that shows a depositing sequence of a dielectric film included in a capacitor shown in FIG. 8; and

FIG. 12 is a flow chart that shows a depositing sequence of a dielectric film included in a capacitor shown in FIG. 9.

### DETAILED DESCRIPTION OF THE PREFERRED EMBODIMENTS

The invention will be described herein with reference to illustrative embodiments. Those skilled in the art will recognize that many alternative embodiments can be accomplished using the teachings of the present invention and that the invention is not limited to the embodiments illustrated here for explanatory purposes.

### First Embodiment

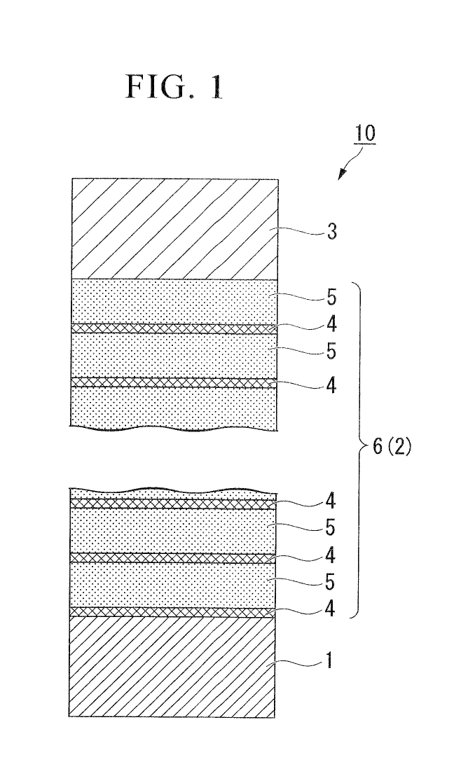

FIG. 1 shows a cross-sectional view of a capacitor according to a first embodiment of the present invention. As shown in FIG. 1, a capacitor 10 includes an under electrode 1, a dielectric film 2, and an upper electrode 3 which are stacked in this sequence.

Materials that compose the under electrode 1 and the upper electrode 13 are not especially restricted. Any electrode materials which are generally employed in the capacitor can be employed. As set forth, metal nitrides such as titanium nitride (TiN), tantalum nitride (TaN) and the like, and metals such as ruthenium (Ru), iridium (Ir), platinum (Pt), alloys including at least one of the metal and the like, are mentioned. When the dielectric film 2 includes an aluminum oxide film and a titanium oxide film stacked alternately, as is described later, ruthenium, iridium, platinum and their alloys are preferable as the under electrode 1 and the upper electrode 3. Due to a narrow bandgap of a titanium oxide film, when the dielectric film includes the titanium oxide film, a leakage current of the capacitor tends to increase. However, when the dielectric film combines with and contacts ruthenium, iridium and platinum, the leakage current can be suppressed since a band offset becomes large. Alternately, conductive oxides that include ruthenium or iridium can be employed as the under electrode 1 and the upper electrode 3, for example, RuO₂, IrO₂, SrRuO₃ and the like.

The dielectric film 2 of the present embodiment includes a composite oxide film 6 which is, for example, represented by a composition formula of AlₓTi_{y}O_{z}, where x, y and z represent the atomic %.

The composite oxide film 6 with the composition formula can provide the high relative dielectric permittivity and suppress the leakage current in the range of a relative thin EOT. For this reason, by using the dielectric film 2 which includes the composite oxide film 6, the capacitor is capable of obtaining a large capacitance with a low leakage current even if there is a decrease in the minimum processing dimension of the capacitor.

According to the dielectric film 2 which includes the composite oxide film 6, it is important that an aluminum composition fits within an appropriate range, where the aluminum composition is a ratio of the aluminum composition ratio x with respect to a total of the aluminum composition ratio x and the titanium composition ratio y, that is [x/(x+y)]×100 in percent, for the composition formula of AlₓTi_{y}O_{z}. Hereinafter, the ratio of the aluminum composition ratio x with respect to the total of the aluminum composition ratio x and the titanium composition ratio y is simply called the “aluminum composition”.

The aluminum composition of the composite oxide 6 is preferably set in the range of 7% to 35%. If the aluminum composition is smaller than 7%, a characteristic of AlₓTi_{y}O_{z} is close to that of the titanium oxide so that the leakage current tends to increase. Moreover, since the crystallization temperature is decreased, the crystallization of AlₓTi_{y}O_{z} occurs, for example, by an annealing process after a film deposition, thereby, the crystallized portion of AlₓTi_{y}O_{z} may cause the leakage current. On the other hand, if the aluminum composition is larger than 35%, the relative dielectric permittivity of AlₓTi_{y}O_{z} is close to that of the aluminum oxide. Therefore, a sufficient relative dielectric permittivity of AlₓTi_{y}O_{z} may not be obtained for a minimum processing dimension of the capacitor below 60 nm. Moreover, the leakage current tends to increase in the range of a relatively thin EOT.

Alternately, the aluminum composition of the composite oxide 6 is preferably within a further appropriate range with respect to materials that are provided with the under electrode 1 and the upper electrode 3.

For example, if the under electrode 1 and the upper electrode 3 include metal nitrides as a main material, the aluminum composition of the composite oxide 6 is more preferably set in the range of 15% to 35%. If the under electrode 1 and the upper electrode 3 include ruthenium, iridium, platinum, and their alloys as the main material, the aluminum composition of the composite oxide 6 is more preferably set in the range of 7% to 15%.

If a stoichiometry is complied in AlₓTi_{y}O_{z} which includes Al₂O₃ and TiO₂, the relation of z=(1.5+2y) is obtained. Therefore, in order to comply with 7≦[x/(x+y)]×100≦35, x, y and z are obtained as follows: 2.36≦x×100≦12.39; 23.01≦y×100≦31.37; and 64.60≦z×100≦66.27.

Alternately, in order to comply with 7≦[x/(x+y)]×100≦15, x, y and z are obtained as follows: 2.36≦x×100≦5.13; 29.06≦y×100≦31.37; and 65.81≦z×100≦66.27. However, since an oxygen composition ratio of the composite oxide film 6 is not necessary to comply with the stoichiometry, the range of the oxygen composition is not limited by the above described relation.

The composite oxide film 6 can be formed by physical vapor deposition methods, such as a vacuum evaporation method, a sputtering method, an ion plating method, a molecular beam epitaxy method and a laser ablation method; and a chemical vapor deposition (CVD) method; and an atomic layer deposition (ALD) method. Among those methods, the composite oxide film 6 preferably includes the aluminum oxide film and the titanium oxide film in which they are alternately stacked and deposited by an atomic layer deposition method.

According to the atomic layer deposition method, for example, a gas of precursor which includes aluminum (aluminum precursor) is supplied to a reactor. Aluminum which is generated from the aluminum precursor gas through a chemical reaction is deposited on a deposition plane so that an aluminum film (having a layer thickness of approximately 1 monolayer) is obtained. After that, an oxidization gas is supplied to the reactor so that the aluminum film is converted into the aluminum oxide film 4 by oxidizing the aluminum film. The aluminum deposition process and the oxidization process alternate and repeat until the aluminum oxide film 4 is deposited and reaches a predetermined layer thickness. Subsequently,a gas of precursor which includes titanium (titanium precursor) is supplied to the reactor. Titanium which is generated from the titanium precursor gas through the chemical reaction is deposited on the deposition plane so that a titanium film (having a layer thickness of approximately 1 monolayer) is obtained. After that, the oxidization gas is supplied to the reactor so that the titanium film is converted into the titanium oxide film 5 by oxidizing the titanium film. The titanium deposition process and the oxidization process alternate and repeat until the titanium oxide film 5 is deposited and reaches the predetermined layer thickness. The formation processes of the aluminum oxide film 4 and the titanium oxide film 5 alternate and repeat so that the composite oxide film is formed.

According to the atomic layer deposition method, an ultrathin film is formed wherein one cycle of the atomic layer deposition method corresponds to approximately 1 monolayer thickness. The deposition of the ultrathin film has the same deposition rate for the entire deposition area. Therefore, the layer thickness of the ultrathin film can be precisely controlled at an atomic level and a uniform ultrathin film can be formed with reproducibility. Furthermore, a film having high step coverage can be provided by the atomic layer deposition method.

If a ratio between a cycle number A of the atomic layer deposition method for the aluminum oxide film 4 and a cycle number B of the atomic layer deposition method for the titanium oxide film 5 is varied, the aluminum composition ratio x and the titanium composition ratio y can be easily controlled. For this reason, the composite oxide film 6 can provide a desired effective-relative-dielectric-permittivity between those of the aluminum oxide and the titanium oxide (9 through 80).

According to the composite oxide film 6 in which the aluminum oxide film 4 and the titanium oxide film 5 are alternately stacked and deposited by the atomic layer deposition method, a thermal stability of the titanium oxide film 5 is enhanced due to an effect of aluminum. Therefore, the composite oxide film 6 requires a crystallization temperature higher than 750° C. For this reason, if an annealing process is performed at approximately 700° C., for example, after the composite oxide film 6 is deposited, a crystallization of the composite oxide film 6 is suppressed so as to maintain an amorphous state. Therefore, an enlargement of the leakage current due to the crystallization can be prevented.

According to the composite oxide film 6 deposited by the atomic layer deposition method, each layer which is formed by each cycle of the atomic layer deposition method dose not abruptly switch to another layer. For example, at an interface between the aluminum oxide film 4 and the titanium oxide film 5, there exists an intermixing of the aluminum oxide film 4 and the titanium oxide film 5 as a combinatorial film. In the present invention, the composite oxide film in which the aluminum oxide film and the titanium oxide film are alternately stacked and deposited by the atomic layer deposition method comprises includes the oxide film having the combinatorial film.

According to the present embodiment, the composite oxide film 6 includes, in sequence, the under electrode 1, the aluminum oxide film 4 and the titanium oxide film 5 that are alternately deposited and repeated by the atomic layer deposition method. The composite oxide film 6 is terminated by the titanium oxide film 5 for the upper electrode 3 side.

These layer thicknesses of the aluminum oxide film 4, the titanium oxide film 5 and the composite oxide film 6 can be controlled by the cycle number of each process of the atomic layer deposition method.

### Method of Manufacturing the Capacitor According to the First Embodiment

Next, a method of manufacturing the capacitor according to the first embodiment will be described hereinbelow.

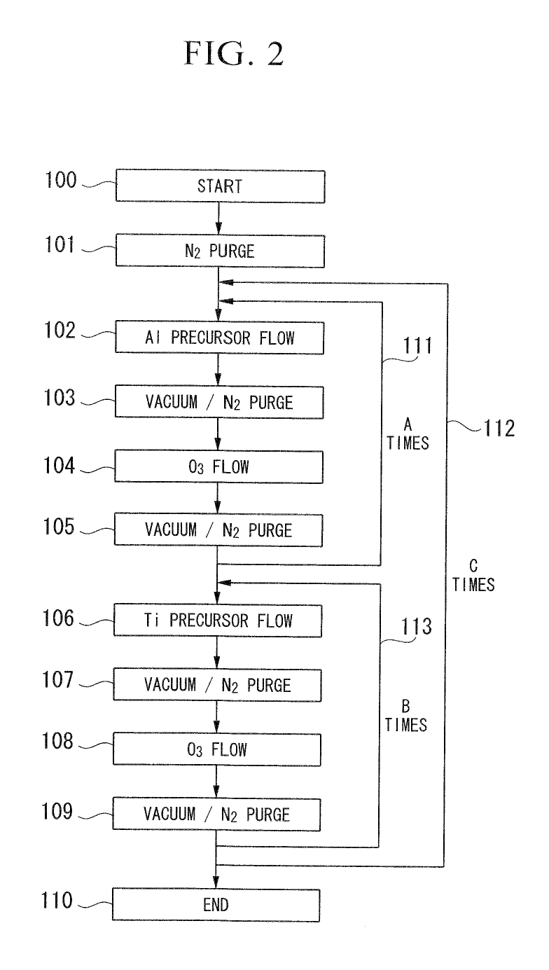

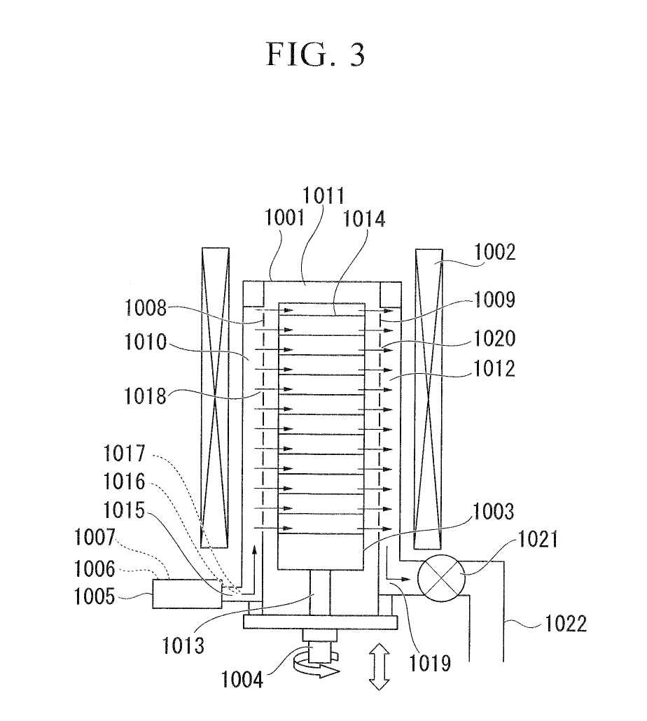

FIG. 2 shows a flow chart of a deposition sequence of the dielectric film (composite oxide film) by the atomic layer deposition method for the capacitor according to a first embodiment. FIG. 3 shows an example of an apparatus that forms the dielectric film by the atomic layer deposition method.

A constitution of the film deposition apparatus is described.

The capacitor manufacturing apparatus shown in FIG. 3 is constituted to form the dielectric film 2 with batch processing for a plurality of wafers.

The capacitor manufacturing apparatus includes a reaction chamber 1001 which is made of quartz, a heater 1002 that heats within the reaction chamber 1001, a boat 1003 which is provided in the reaction chamber 1001, a rotation drive portion 1004 that rotates the boat 1003, and a plurality of injectors 1005, 1006 and 1007 that supplies gasses into the reaction chamber 1001.

A space in the reaction chamber 1001 is separated into three areas by two walls 1008 and 1009 which are provided in place for each inner wall of the reaction chamber. One of the three areas (the left side) is a supply chamber 1010, one of the three areas (the middle) is a deposition chamber 1011 and one of the three areas (the right side) is an exhaust chamber 1012, as shown in FIG. 3.

In the deposition chamber 1011, the boat 1003 which is connected with a pivot portion 1013 is provided and the pivot portion 1013 is connected with the rotation drive portion 1004. The boat 1003 is constituted to enable separating and holding a plurality of wafers 1014 in parallel along the vertical direction (In the present embodiment, a wafer number is 100). When the plurality of wafers 1014 is attached to the boat 1003 and the pivot portion 1013 is rotated by the rotation drive portion 1004, the plurality of wafers 1014 which is attached to the boat 1 003 is rotated around the pivot portion 1013. Therefore, the gases which are provided into the reaction chamber 1001 are uniformly supplied to surfaces of the plurality of wafers 1014, and the depositions of the aluminum oxide film 4 and the titanium oxide film 5 by the atomic layer deposition method are made with uniformity.

The supply chamber 1010 includes three gas inlets 1015, 1016 and 1017, and a plurality of gas supply slits 1018. The gas inlets 1015, 1016 and 1017 connect with the first injector 1005, the second injector 1006 and the third injector 1007, respectively, wherein the first injector 1005 supplies the aluminum precursor and a nitrogen gas, the second injector 1006 supplies the titanium precursor and the nitrogen gas, and the third injector 1007 supplies an ozone gas and the nitrogen gas. On the other hand, the first injector 1005 may supply the aluminum precursor, the titanium precursor and the nitrogen gas, and the second injector 1006 may be omitted.

A plurality of the gas supply slits 1018 is provided in the wall 1008 that separates the supply chamber 1010 and the deposition chamber 1011, in parallel along the vertical direction. Each gas supply slit 1018 is separated with a constant interval and located to correspond to a space between each wafer. The gases which are provided into the supply chamber 1010 via the injectors 1005, 1006 and 1007 pass through the gas supply slits 1018 and are provided near the surface of each wafer 1014.

The exhaust chamber 1012 includes a gas outlet 1019 which opens to an outside of the reaction chamber 1001, and a plurality of gas exhaust slits 1020. The gas outlet 1019 is connected with one side of a valve 1021, and another side of the valve 1021 is connected with one side of an exhaust port 1022. Another side of the exhaust port is connected with an exhaust pump not shown. An exhaust portion includes the valve 1021, the exhaust port 1022, and the exhaust pump, in the film deposition apparatus.

A plurality of the gas exhaust slits 1020 is provided in the wall 1009 that separates the exhaust chamber 1012 and the deposition chamber 1011, in parallel along the vertical direction with corresponding to the gas supply slits 1018.

When the valve 1021 opens, the gases which are provided into the deposition chamber 1011 via the supply chamber 1010 pass through the gas exhaust slits 1020 and are exhausted into the exhaust chamber 1012, then, the gases pass the gas outlet 1019, the valve 1021 and the exhaust port 1022, and are exhausted to the outside of the reaction chamber 1001. In this case, in the deposition chamber 1011, a laminar flow passes from the each gas supply slit 1018 to the corresponding gas exhaust slit 1020. Thereby, the gases which are provided to the deposition chamber 1011 are uniformly supplied to surfaces of the each wafer 1014, and the depositions of the aluminum oxide film 4 and the titanium oxide film 5 by the atomic layer deposition method are made with uniformity.

The film deposition apparatus further includes a control portion not shown that controls the gas being supplied by the gas injectors 1005, 1006 and 1007, and the gas being exhausted by the gas exhaust portion. The control portion controls and repeats gas supply by the gas injectors 1005, 1006 and 1007, and gas exhaust by the gas exhaust portion to obtain a design value of the aluminum composition ratio and the titanium composition ratio, based on a predetermined relationship between the cycle number A of the atomic layer deposition method for the aluminum oxide film and the aluminum composition ratio, and also the relationship between the cycle number B of the atomic layer deposition method for the titanium oxide film and the titanium composition ratio, of the composite oxide film.

The capacitor is manufactured by the above-mentioned apparatus, as follows.

Initially, the wafer 1014 is prepared to form the capacitor 10 thereon. Then, the under electrode 1 is formed at each capacitor formation area on the wafer 1014. The under electrode 1 is subjected, for example, to a patterning process to provide the shape of the under electrode 1 combined with a photolithography technology, after a conductive film is formed and covers the entire surface of the wafer 1014. Thereby, the under electrode 1 is obtained. Methods that form the under electrode 1 are a physical vapor deposition method, a chemical vapor phase deposition method or the like.

Then, the dielectric film 2 is deposited on the under electrode 1 according to the deposition sequence of the dielectric film shown in FIG. 2, by the film deposition apparatus shown in FIG. 3.

100 pieces of the wafers 1014 are attached to the boat 1003. The boat 1003 is loaded into the deposition chamber 1011. Then, operations of each portion start when the valve 1021 is opened. Therefore, the boat 1003 rotates around the pivot portion 1013, and the inside of the reaction chamber 1001 reaches a predetermined temperature. The chambers 1010, 1011 and 1012 within the reaction chamber 1001 are exhausted to reach a predetermined pressure.

Then, the nitrogen gas is supplied to the supply chamber 1010 through the third injector 1007. The nitrogen gas which is supplied to the supply chamber 1010 passes through the each gas supply slit 1018 and is provided between respective wafers 1014 in the deposition chamber 1011. The nitrogen gas passes through the each gas exhaust slit 1020 and is exhausted to the gas exhaust chamber 1012. The nitrogen gas which is exhausted to the gas exhaust chamber 1012 passes through the gas outlet 1019, the valve 1021 and the exhaust port 1022, and is exhausted to the outside of the reaction chamber 1001. In this case, the laminar flow of the nitrogen gas appears between the respective wafers 1014. Therefore, a nitrogen purge process is performed for the surface of the wafer 1014 (step 101).

Then, the aluminum precursor gas is supplied to the supply chamber 1010 through the first injector 1005. When the aluminum precursor gas is supplied to the supply chamber 1010, the same as the nitrogen gas in step 101, the laminar flow of the aluminum precursor gas appears between the respective wafers 1014. The aluminum precursor gas is thermally decomposed so that aluminum of a component element thereof is adsorbed on the surface of the wafer 1014, and forms an aluminum film having a layer thickness of approximately one monolayer (step 102).

After that, supply of the aluminum precursor gas into the supply chamber 1010 through the first injector 1005 is stopped. The aluminum precursor gas which remains in the deposition chamber 1011 passes through each exhaust slit 1020 and is exhausted to the gas exhaust chamber 1012. The aluminum precursor gas which is exhausted to the gas exhaust chamber 1012 passes through the gas outlet 1019, the valve 1021 and the exhaust port 1022, and is exhausted to the outside of the reaction chamber 1001. Then, the nitrogen gas is supplied to the supply chamber 1010 through the third injector 1007. When the nitrogen gas is supplied to the supply chamber 1010, the same as the nitrogen gas in step 101, the laminar flow of the nitrogen gas appears between the respective wafers 1014. By the nitrogen gas, excess aluminum that is adsorbed on the surface of the wafers 1014 is removed (step 103).

Then, the oxidization gas is supplied to the supply chamber 1010 through the third injector 1007. When the oxidization gas is supplied to the supply chamber 1010, the same as the nitrogen gas in step 101, the laminar flow of the oxidization gas appears between the respective wafers 1014. Since the oxidization gas reacts with the aluminum film that is formed on the surface of the wafers 1014, the aluminum oxide film is formed (step 104).

After that, supply of the oxidization gas into the supply chamber 1010 through the third injector 1007 is stopped. The oxidization gas which remains in the deposition chamber 1011 passes through each exhaust slit 1020 and is exhausted to the gas exhaust chamber 1012. The oxidization gas which is exhausted to the gas exhaust chamber 1012 passes through the gas outlet 1019, the valve 1021 and the exhaust port 1022, and is exhausted to the outside of the reaction chamber 1001. Then, the nitrogen gas is supplied to the supply chamber 1010 through the third injector 1007. When the nitrogen gas is supplied to the supply chamber 1010, the same as the nitrogen gas in step 101, the laminar flow of the nitrogen gas appears between the respective wafers 1014. By the nitrogen gas, an excess oxidization agent and the like that are adsorbed on the surface of the aluminum oxide film are removed (step 105).

The above described steps 102 through 105 repeat until the aluminum oxide film is deposited and reaches a predetermined layer thickness. Therefore, the aluminum oxide film 4 is obtained (step 111: aluminum oxide film formation process).

Next, the titanium precursor gas is supplied to the supply chamber 1010 through the second injector 1006. When the titanium precursor gas is supplied to the supply chamber 1010, the same as the nitrogen gas in step 101, the laminar flow of the titanium precursor gas appears between the respective wafers 1014. The titanium precursor gas is thermally decomposed so that the titanium of a component element thereof is adsorbed on the surface of the aluminum oxide film 4, and forms a titanium film having a layer thickness of approximately one monolayer (step 106).

After that, supply of the titanium precursor gas into the supply chamber 1010 through the second injector 1006 is stopped. The titanium precursor gas which remains in the deposition chamber 1011 passes through the each exhaust slit 1020 and is exhausted to the gas exhaust chamber 1012. The titanium precursor gas which is exhausted to the gas exhaust chamber 1012 passes through the gas outlet 1019, the valve 1021 and the exhaust port 1022, and is exhausted to the outside of the reaction chamber 1001. Then, the nitrogen gas is supplied to the supply chamber 1010 through the third injector 1007. When the nitrogen gas is supplied to the supply chamber 1010, as same as the nitrogen gas in step 101, the laminar flow of the nitrogen gas appears between the respective wafers 1014. By the nitrogen gas, excess titanium which is adsorbed on the surface of the aluminum oxide film 4 is removed (step 107).

Then, the oxidization gas is supplied to the supply chamber 1010 through the third injector 1007. When the oxidization gas is supplied to the supply chamber 1010, the same as the nitrogen gas in step 101, the laminar flow of the oxidization gas appears between the respective wafers 1014. Since the oxidization gas reacts with the titanium film that is formed on the surface of the aluminum oxide film 4, the titanium oxide film is formed (step 108).

After that, supply of the oxidization gas into the supply chamber 1010 through the third injector 1007 is stopped. The oxidization gas which remains in the deposition chamber 1011 passes through each exhaust slit 1020 and is exhausted to the gas exhaust chamber 1012. The oxidization gas which is exhausted to the gas exhaust chamber 1012 passes through the gas outlet 1019, the valve 1021 and the exhaust port 1022, and is exhausted to the outside of the reaction chamber 1001. Then, the nitrogen gas is supplied to the supply chamber 1010 through the third injector 1007. When the nitrogen gas is supplied to the supply chamber 1010, the same as the nitrogen gas in step 101, the laminar flow of the nitrogen gas appears between the respective wafers 1014. By the nitrogen gas, an excess oxidization agent and the like that are adsorbed on the surface of the titanium oxide film 5 is removed (step 109).

The above described steps 106 through 109 repeat until the titanium oxide film is deposited and reaches a predetermined layer thickness. Therefore, the titanium oxide film 4 is obtained (step 113: titanium oxide film formation process).

Furthermore, the step 111 (aluminum oxide film formation process) and the step 113 (titanium oxide film formation process) repeat until the composite oxide film 6 is deposited and reaches a predetermined layer thickness. Therefore, the composite oxide film 6, in which the aluminum oxide film 4 and the titanium oxide film 5 alternate and are deposited, is obtained (step 112: composite oxide film formation process).

Finally, the operations of each portion stop. The chambers 1010, 1011 and 1012 within the reaction chamber 1001 reach an atmospheric pressure. Then, the boat 1003 is taken out from the deposition chamber 1011, and the wafers 1014 on which the composite oxide film 6 is deposited are taken out from the boat 1003 (step 110).

With regard to the above described formation process of the dielectric film, trimethylaluminium (TMA) or the like can be employed as the aluminum precursor, titanium tetraisopropoxide (Ti{OCH[CH₃]₂}₄) or the like can be employed as the titanium precursor, and ozone (O₃), H₂O, plasma-activated oxygen or the like can be employed as the oxidization agent. The aluminum precursor, the titanium precursor and the oxidization agent are not limited thereto.

According to the formation process of the composite oxide film 6 by the atomic layer deposition method, the aluminum composition ratio x and the titanium composition ratio y of the composite oxide film 6 can be controlled by the ratio between the cycle number A of steps 102 through 105 and the cycle number B of steps 106 through 109. The layer thickness of the composite oxide film 6 can be controlled by the cycle number C of step 112. The upper electrode 3 is formed on the composite oxide film 6 (dielectric film 2) which is formed by the above described sequence. The upper electrode 3 can be formed the same as the under electrode 1.

According to the method of manufacturing the capacitor, the aluminum oxide film formation process by the atomic layer deposition method and the titanium oxide film formation process by the atomic layer deposition method alternate and repeat so as to form the dielectric film 2.

According to the atomic layer deposition method, an ultrathin film is formed wherein one cycle of the atomic layer deposition method corresponds to approximately 1 monolayer thickness. The deposition of the ultrathin film has the same deposition rate for the entire deposition area. Therefore, the layer thickness of the ultrathin film can be precisely controlled with an atomic level and a uniform ultrathin film can be formed with reproducibility. Furthermore, a film having high step coverage can be provided by the atomic layer deposition method.

If the ratio between the cycle number A of steps 102 through 105 for the aluminum oxide film formation process and the cycle number B of steps 106 through 109 for the titanium oxide film formation process is varied, the aluminum composition ratio x and the titanium composition ratio y of the composite oxide film 6 can be easily controlled. For this reason, the composite oxide film 6 can provide a desired effective-relative-dielectric-permittivity between those of the aluminum oxide and the titanium oxide (9 through 80).

Furthermore, when the dielectric film which includes the composite oxide film 6 is formed, a precursor having a low vapor pressure such as a strontium source is not necessary. Therefore, it is easy to put a practical application.

### Second Embodiment

Next, a capacitor according to a second embodiment will be described hereinbelow.

According to the second embodiment, descriptions for a constitution that is the same as the first embodiment are omitted.

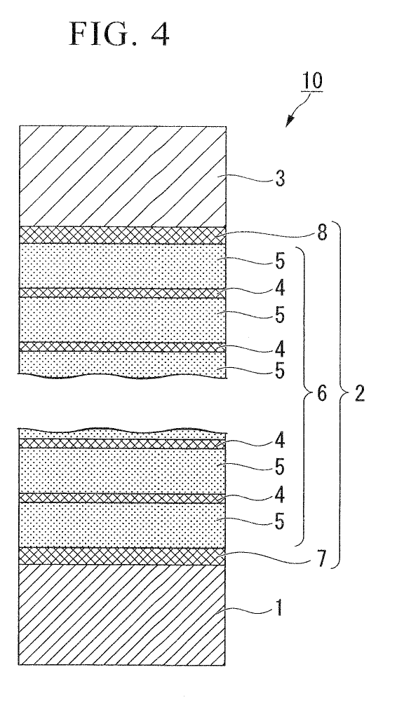

FIG. 4 shows a cross-sectional view of the capacitor according to the present embodiment. Except the constitution of a dielectric film, the capacitor of the present embodiment is the same as the first embodiment.

That is, as shown in FIG. 4, according to the capacitor of the present embodiment, a dielectric film 2 includes: a composite oxide film 6 which is represented by the composition formula of AlₓTi_{y}O_{z}, where x, y and z represent the atomic %; an under aluminum oxide film 7 which is provided between the composite oxide film 6 and an under electrode 1; and an upper aluminum oxide film 8 which is provided between the composite oxide film 6 and an upper electrode 3.

With regard to the composite oxide film 6 of the present embodiment, appropriate ranges of an aluminum composition ratio and a titanium composition ratio, a deposition method are the same as the first embodiment. According to the present embodiment, the composite oxide film 6 includes, in sequence, the under aluminum oxide film 7, the titanium oxide film 5 and the aluminum oxide film 4 that are alternately deposited and repeated by the atomic layer deposition method. The composite oxide film 6 is terminated by the titanium oxide film 5 for the upper aluminum oxide film 8.

The same effect as the first embodiment can be obtained for the present embodiment. According to the capacitor of the present embodiment, since the under aluminum oxide film 7 is provided between the composite oxide film 6 and the under electrode 1 while the upper aluminum oxide film 8 is provided between the composite oxide film 6 and the upper electrode 3, a reaction and an inter-diffusion between the composite oxide film 6 and the under electrode 1, and the reaction and the inter-diffusion between the composite oxide film 6 and the upper electrode 3 are suppressed. Therefore, for example, even if a thermal process is subjected after the capacitor is provided, a degradation of the capacitor characteristic can be prevented by the under aluminum oxide film 7 which is provided between the composite oxide film 6 and the under electrode 1, and the upper aluminum oxide film 8 which is provided between the composite oxide film 6 and the upper electrode 3.

The under aluminum oxide film 7 and the upper aluminum oxide film 8 can be formed by the physical vapor deposition methods described above, the chemical vapor deposition (CVD) method, the atomic layer deposition (ALD) method or the like.

Among those methods, the under aluminum oxide film 7 and the upper aluminum oxide film 8 are preferably deposited by the atomic layer deposition method.

Therefore, the layer thicknesses of the under aluminum oxide film 7 and the upper aluminum oxide film 8 can be precisely controlled at an atomic level and uniformity of the under aluminum oxide film 7 and the upper aluminum oxide film 8 can be realized with reproducibility. Furthermore, films having high step coverage can be provided by the atomic layer deposition method. As a result, advantages of preventing the reaction and the inter-diffusion between the composite oxide film 6 and the under electrode 1, and the reaction and the inter-diffusion between the composite oxide film 6 and the upper electrode 3, can be reliably obtained.

Moreover, when the composite oxide film 6 is deposited by the atomic layer deposition method and both the under aluminum oxide film 7 and the upper aluminum oxide film 8 are also deposited by the atomic layer deposition method, the under aluminum oxide film 7 and the upper aluminum oxide film 8 can be deposited by the film deposition apparatus that form the composite oxide film 6, continuing the composite oxide film 6 formation process. For this reason, there is an advantage in that the capacitor manufacturing process becomes easy.

### Method of Manufacturing the Capacitor According to the Second Embodiment

Next, a method of manufacturing the capacitor according to the second embodiment will be described hereinbelow According to the method of manufacturing the capacitor of the second embodiment, descriptions of the same process for the method of manufacturing the capacitor of the first embodiment are omitted.

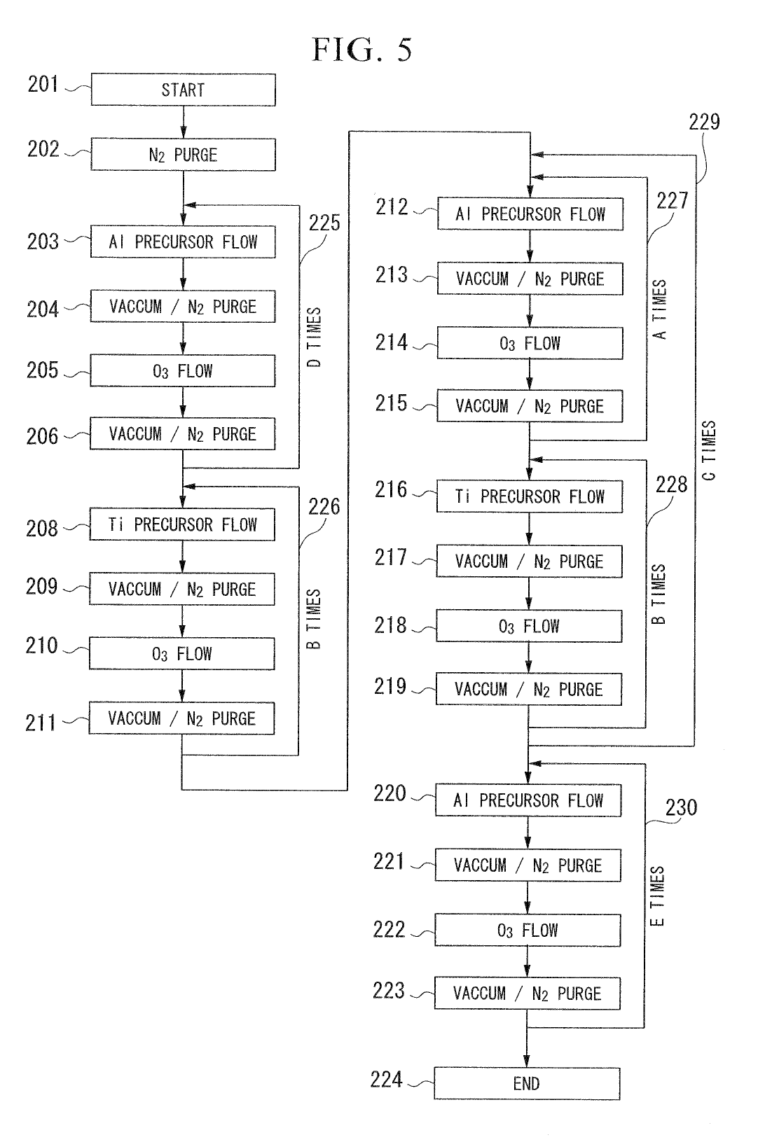

FIG. 5 shows a flow chart of a depositing sequence of the dielectric film according to the second embodiment by the atomic layer deposition method.

Except for the formation process of the dielectric film, the method of manufacturing the capacitor of the present embodiment is the same as the first embodiment.

That is, after the under electrode 1 is formed on the surface of the wafer 1014, the dielectric film 2 is deposited on the under electrode 1 by the film deposition apparatus shown in FIG. 3 (step 201).

100 pieces of the wafers 1014 are attached to the boat 1003. The boat 1003 is loaded into the deposition chamber 1011. Then, operations of each portion start when the valve 1021 is opened. Therefore, the boat 1003 rotates around the pivot portion 1013, and the inside of the reaction chamber 1001 reaches the predetermined temperature. The chambers 1010, 1011 and 1012 within the reaction chamber 1001 are exhausted to reach the predetermined pressure.

Then, the nitrogen gas is supplied to the supply chamber 1010 through the third injector 1007. The nitrogen gas which is supplied to the supply chamber 1010 passes through each gas supply slit 1018 and is provided between the respective wafers 1014 in the deposition chamber 1011. The nitrogen gas passes through the each gas exhaust slit 1020 and is exhausted to the gas exhaust chamber 1012. The nitrogen gas which is exhausted to the gas exhaust chamber 1012 passes through the gas outlet 1019, the valve 1021 and the exhaust port 1022, and is exhausted to the outside of the reaction chamber 1001. In this case, the laminar flow of the nitrogen gas appears between the respective wafers 1014. Therefore, the nitrogen purge process is performed for the surface of the wafer 1014 (step 202).

Then, the aluminum precursor gas is supplied to the supply chamber 1010 through the first injector 1005. When the aluminum precursor gas is supplied to the supply chamber 1010, the same as the nitrogen gas in step 202, the laminar flow of the aluminum precursor gas appears between the respective wafers 1014. The aluminum precursor gas is thermally decomposed so that aluminum of the component element thereof is adsorbed on the surface of the wafer 1014, and forms an aluminum film having a layer thickness of approximately one monolayer (step 203).

After that, supply of the aluminum precursor gas into the supply chamber 1010 through the first injector 1005 is stopped. The aluminum precursor gas which remains in the deposition chamber 1011 passes through each exhaust slit 1020 and is exhausted to the gas exhaust chamber 1012. The aluminum precursor gas which is exhausted to the gas exhaust chamber 1012 passes through the gas outlet 1019, the valve 1021 and the exhaust port 1022, and is exhausted to the outside of the reaction chamber 1001. Then, the nitrogen gas is supplied to the supply chamber 1010 through the third injector 1007. When the nitrogen gas is supplied to the supply chamber 1010, the same as the nitrogen gas in step 202, the laminar flow of the nitrogen gas appears between the respective wafers 1014. By the nitrogen gas, excess aluminum that is adsorbed on the surface of the wafers 1014 is removed (step 204).

Then, the oxidization gas is supplied to the supply chamber 1010 through the third injector 1007. When the oxidization gas is supplied to the supply chamber 1010, the same as the nitrogen gas in step 202, the laminar flow of the oxidization gas appears between the respective wafers 1014. Since the oxidization gas reacts with the aluminum film that is formed on the surface of the wafers 1014, the aluminum oxide film is formed (step 205).

After that, supply of the oxidization gas into the supply chamber 1010 through the third injector 1007 is stopped. The oxidization gas which remains in the deposition chamber 1011 passes through each exhaust slit 1020 and is exhausted to the gas exhaust chamber 1012. The oxidization gas which is exhausted to the gas exhaust chamber 1012 passes through the gas outlet 1019, the valve 1021 and the exhaust port 1022, and is exhausted to the outside of the reaction chamber 1001. Then, the nitrogen gas is supplied to the supply chamber 1010 through the third injector 1007. When the nitrogen gas is supplied to the supply chamber 1010, the same as the nitrogen gas in step 202, the laminar flow of the nitrogen gas appears between the respective wafers 1014. By the nitrogen gas, an excess oxidization agent and the like that are adsorbed on the surface of the aluminum oxide film are removed (step 206).

The above described steps 203 through 206 repeat until the aluminum oxide film is deposited and reaches the predetermined layer thickness. Therefore, the aluminum oxide film 4 is obtained (step 225: under aluminum oxide film formation process).

Next, the titanium precursor gas is supplied to the supply chamber 1010 through the second injector 1006. When the titanium precursor gas is supplied to the supply chamber 1010, the same as the nitrogen gas in step 202, the laminar flow of the titanium precursor gas appears between the respective wafers 1014. The titanium precursor gas is thermally decomposed so that titanium of the component element thereof is adsorbed on the surface of the under aluminum oxide film 7, and forms a titanium film having a layer thickness of approximately one monolayer (step 208).

After that, supply of the titanium precursor gas into the supply chamber 1010 through the second injector 1006 is stopped. The titanium precursor gas which remains in the deposition chamber 1011 passes through each exhaust slit 1020 and is exhausted to the gas exhaust chamber 1012. The titanium precursor gas which is exhausted to the gas exhaust chamber 1012 passes through the gas outlet 1019, the valve 1021 and the exhaust port 1022, and is exhausted to the outside of the reaction chamber 1001. Then, the nitrogen gas is supplied to the supply chamber 1010 through the third injector 1007. When the nitrogen gas is supplied to the supply chamber 1010, the same as the nitrogen gas in step 202, the laminar flow of the nitrogen gas appears between the respective wafers 1014. By the nitrogen gas, excess titanium which is adsorbed on the surface of the under aluminum oxide film 7 is removed (step 209).

Then, the oxidization gas is supplied to the supply chamber 1010 through the third injector 1007. When the oxidization gas is supplied to the supply chamber 1010, the same as the nitrogen gas in step 202, the laminar flow of the oxidization gas appears between the respective wafers 1014. Since the oxidization gas reacts with the titanium film that is formed on the surface of the under aluminum oxide film 7, the titanium oxide film is formed (step 210).

After that, supply of the oxidization gas into the supply chamber 1010 through the third injector 1007 is stopped. The oxidization gas which remains in the deposition chamber 1011 passes through each exhaust slit 1020 and is exhausted to the gas exhaust chamber 1012. The oxidization gas which is exhausted to the gas exhaust chamber 1012 passes through the gas outlet 1019, the valve 1021 and the exhaust port 1022, and is exhausted to the outside of the reaction chamber 1001. Then, the nitrogen gas is supplied to the supply chamber 1010 through the third injector 1007. When the nitrogen gas is supplied to the supply chamber 1010, the same as the nitrogen gas in step 202, the laminar flow of the nitrogen gas appears between the respective wafers 1014. An excess oxidization agent or the like that is adsorbed on the surface of the titanium oxide film 5 is removed by the nitrogen gas (step 211).

The above described steps 208 through 211 repeat until the titanium oxide film is deposited and reaches the predetermined layer thickness. Therefore, the titanium oxide film 5 is obtained (step 226: titanium oxide film formation process).

Subsequently, a same sequence as steps 203 through 206 repeats until the aluminum oxide film is deposited and reaches the predetermined layer thickness (steps 212 through 215). Therefore, the aluminum oxide film 4 is obtained on the titanium oxide film 5 (step 227: aluminum oxide film formation process).

Then, a same sequence as steps 208 through 211 repeats until the titanium oxide film is deposited and reaches the predetermined layer thickness (steps 216 through 219). Therefore, the titanium oxide film 5 is obtained on the aluminum oxide film 4 (step 228: titanium oxide film formation process).

Furthermore, the above described steps 227 and 228 repeat until the composite oxide film is deposited and reaches the predetermined layer thickness. Therefore, the composite oxide film 6 in which the aluminum oxide film 4 and the titanium oxide film 5 alternate and are deposited is obtained (step 229: composite oxide film formation process).

Then, the same sequence as steps 203 through 206 repeats until the aluminum oxide film is deposited and reaches the predetermined layer thickness. Therefore, the upper aluminum oxide film 4 is obtained on the composite oxide film 6 (step 230: upper aluminum oxide film formation process).

Finally, the operations of each portion stop. The chambers 1010, 1011 and 1012 within the reaction chamber 1001 reach an atmospheric pressure. Then, the boat 1003 is taken out from the deposition chamber 1011 and the wafers 1014 on which the under aluminum oxide film 7, the composite oxide film 6, and the upper oxide film 8 are deposited is taken out from the boat 1003 (step 224).

By the above described processes, the dielectric film 2 that includes the under aluminum oxide film 7, the composite oxide film 6, and the upper oxide film 8 can be obtained.

With regard to the aluminum precursor gas, the titanium precursor gas and the oxidization gas, the same materials as those of the first embodiment can be employed. Flow rates of each gas and appropriate deposition temperature ranges are also the same as those of the first embodiment.

According to the formation process of the composite oxide film 6 by the atomic layer deposition method, the aluminum composition ratio x and the titanium composition ratio y of the composite oxide film 6 can be controlled by the ratio between the cycle number A of steps 212 through 215 and the cycle number B of steps 216 through 219. The layer thickness of the composite oxide film 6 can be controlled by the cycle number C of step 229.

### [Semiconductor Memory Device]

Subsequently, a semiconductor memory device to which the capacitor according to the present invention is applied will be described below. In this case, the DRAM is explained as an example of the application of the capacitor.

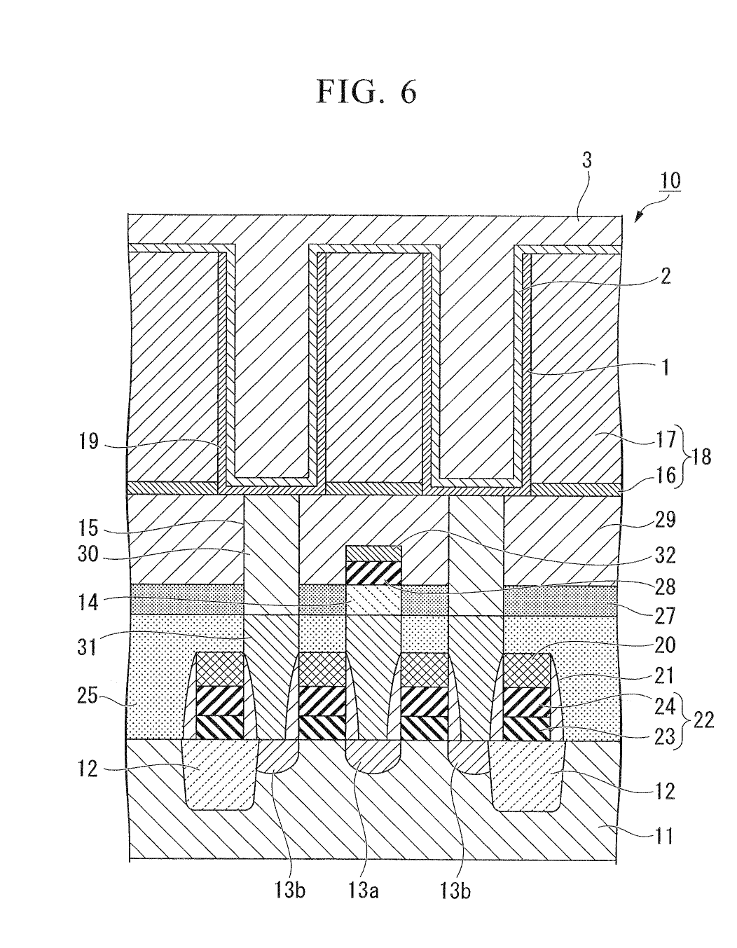

FIG. 6 shows a cross-sectional view of a semiconductor memory device employing the capacitor according to the present invention.

In FIG. 6, a semiconductor substrate 11 includes a semiconductor such as silicon doped with a p-type impurity (boron or the like).

A device isolation area 12 is provided at a position except for a transistor fabrication area on the semiconductor substrate 11 by a shallow trench isolation (STI) method, and insulates a transistor (selection transistor) from a neighbor thereof.

In the transistor fabrication area, for example, a silicon oxide film which is provided by a thermal oxidization method is formed as a gate insulation film (not shown) on the semiconductor substrate 11.

A gate electrode 22 is formed on the gate insulation film and includes, for example, multiple layers of a poly silicon film 23 and a metal film 24. A poly silicon film doped with impurity during the chemical vapor deposition can be employed as the poly silicon film 23. The metal film 24 is provided with refractory metals such as tungsten (W), tungsten silicide (WSi) and the like.

An insulation film 20 which is provided with a silicon nitride film or the like is formed on the gate electrode 22. A side wall 21 which is provided with the silicon nitride film or the like is formed on a side wall of the gate electrode 22. A source diffusion film 13b is formed at one side of the gate electrode 22 around a surface of the semiconductor substrate 11. A drain diffusion film 13a is formed at another side of the gate electrode 22 around the surface of the semiconductor substrate 11.

A contact plug 31 is connected with the source diffusion film 13b or the drain diffusion film 13b and includes the poly silicon doped with a predetermined impurity concentration. The contact plug 31 is provided in each contact hole which is formed by the insulation film 20 and the side wall 21. A first interlayer insulation film 25 is provided in a groove between each contact plug 31 and the neighbor thereof. That is, the first interlayer insulation film 25 insulates each contact plug 31.

A second interlayer insulation film 27 and a third interlayer insulation film 25 is provided all over a surface of the contact plug 31 and the first insulation film 25.

In order to make a surface of the contact plug 31 connecting with the drain diffusion film 13a appear, a contact hole that passes through the second interlayer insulation film 27 is provided. A bit line contact plug 14 is formed in the contact hole and includes titanium/titanium nitride/tungsten metal films.

A bit line 28 which includes a tungsten metal film and a silicon nitride film 32 are formed on the bit line contact plug 14. That is, the bit line 28 is connected with the drain diffusion film 13a of a MOS transistor via the contact plug 31 and the bit line contact plug 14.

In order to make a surface of the contact plug 31 connecting with the source diffusion film 13a of the MOS transistor appear, a capacitor contact hole 15 that passes through the second interlayer insulation film 27 and the third interlayer insulation film 29 is provided.

A capacitor contact plug 30 is formed in the capacitor contact hole 15 and includes the poly silicon doped with phosphorous.

A fourth interlayer insulation film 18 which includes an oxide film 17 and a stopper silicon nitride film 16 is provided all over a surface of the third interlayer insulation layer 29 and the capacitor contact plug 30. A capacitor cylinder pore 19 for a core of the capacitor 10 is provided above the capacitor contact plug 30.

The capacitor 10 of the present invention is provided on a bottom plane and an inner wall of the capacitor cylinder pore 19.

According to the above described semiconductor memory device, since the capacitor 10 of the present invention is included, a large capacitance can be obtained even if there is a decrease in a DRAM half pitch.

Accordingly, while the preferred embodiments of the present invention have been described and illustrated above, it should be understood that, with regard to the capacitor, the method of manufacturing the capacitor, the capacitor manufacturing apparatus, and the semiconductor memory device, the constitutions thereof are not to be considered as limiting. Additions, omissions, substitutions and other modifications can be made without departing from the spirit or scope of the present invention.

For example, according to the embodiment, although the film deposition apparatus that forms the dielectric film is constituted as a batch type, it does not matter and the film deposition apparatus may be constituted as s flat sheet type.

### Embodiments

Hereinbelow, the present invention will be further set forth by embodiments.

### 1. Manufacturing the Semiconductor Memory Devices

### EXAMPLES 1 THROUGH 5

Wafers, in which each portion except the capacitor is provided as shown in FIG. 6, are prepared. Then, a titanium nitride (TiN) film is formed in the capacitor cylinder pore. The titanium nitride film is subjected to the patterning process combined with the photolithography technology so that the under electrode is provided.

Then, by using the film deposition apparatus shown in FIG. 3, the composite oxide film which includes AlₓTi_{y}O_{z} is formed according to the deposition sequence shown in FIG. 2.

In this case, trimethylaluminium (TMA) is employed as the aluminum precursor, titanium tetraisopropoxide (Ti {OCH[CH₃]₂}₄) is employed as the titanium precursor, and ozone is employed as the oxidization agent. The process time for the each step is set to 60 sec.

The cycle number A of steps 102 through 105 and the cycle number B of steps 106 through 109 are varied as shown in TABLE 1. The equivalent oxide film thickness (EOT) of the composite oxide film is varied ranging from 0.3 nm to 2.0 nm by varying the cycle number C.

Subsequently, the titanium nitride (TiN) is formed on the composite oxide film (dielectric film). The titanium nitride film is subjected to the patterning process combined with the photolithography technology so that the upper electrode is provided.

The DRAMs are obtained by the above described processes.

### EXAMPLES 6 AND 7

The DRAMs are manufactured, except for an employment of a platinum film for the under electrode and the upper electrode, through the same processes according to the examples 1 through 5.

According to the DRAMs which are manufactured as described above, the aluminum composition [x/(x+y)]×100 and the effective-relative-dielectric-permittivity of the dielectric films are measured. Results are shown in TABLE 1. The aluminum composition is measured by using a Rutherford back scattering (RBS) method.

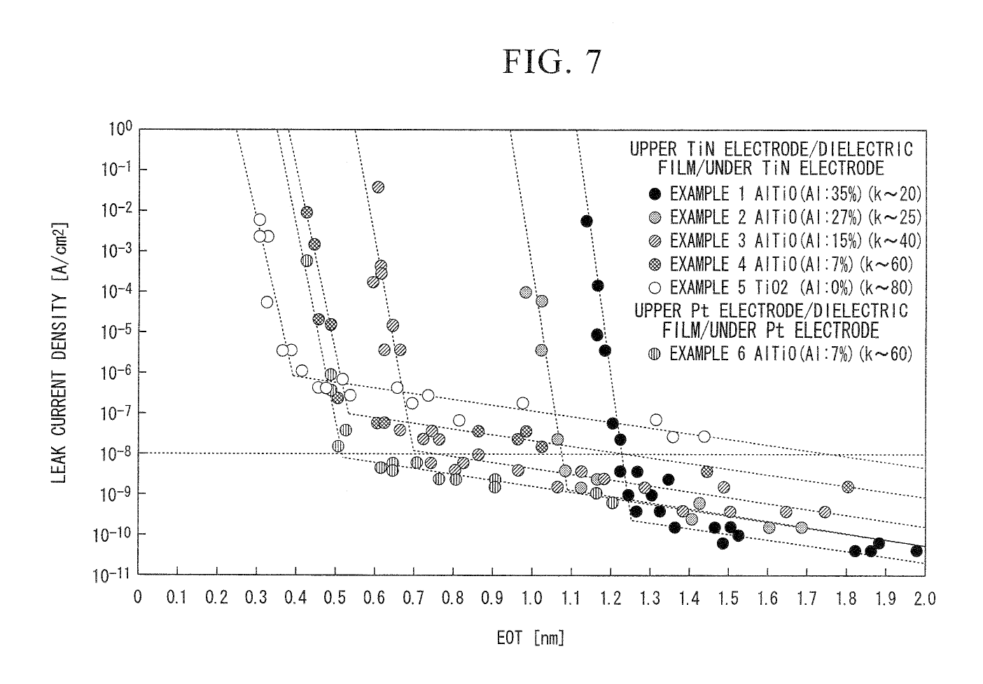

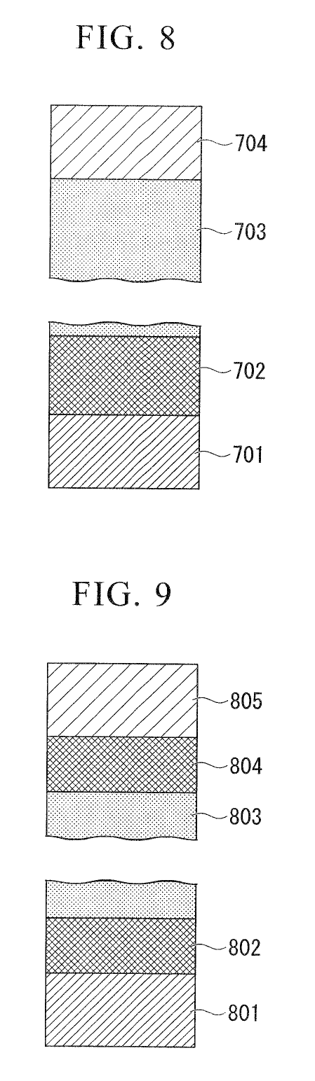

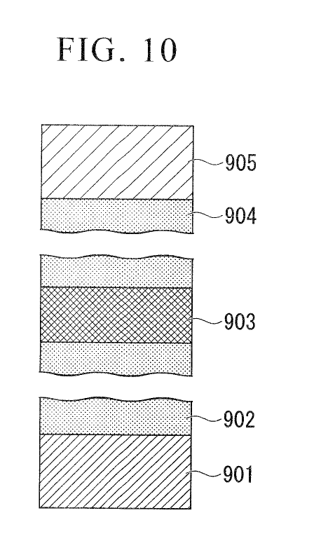

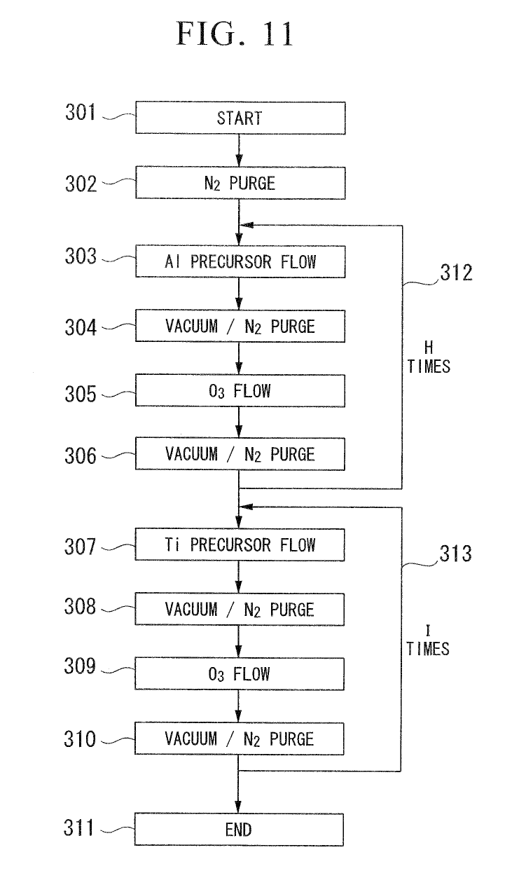

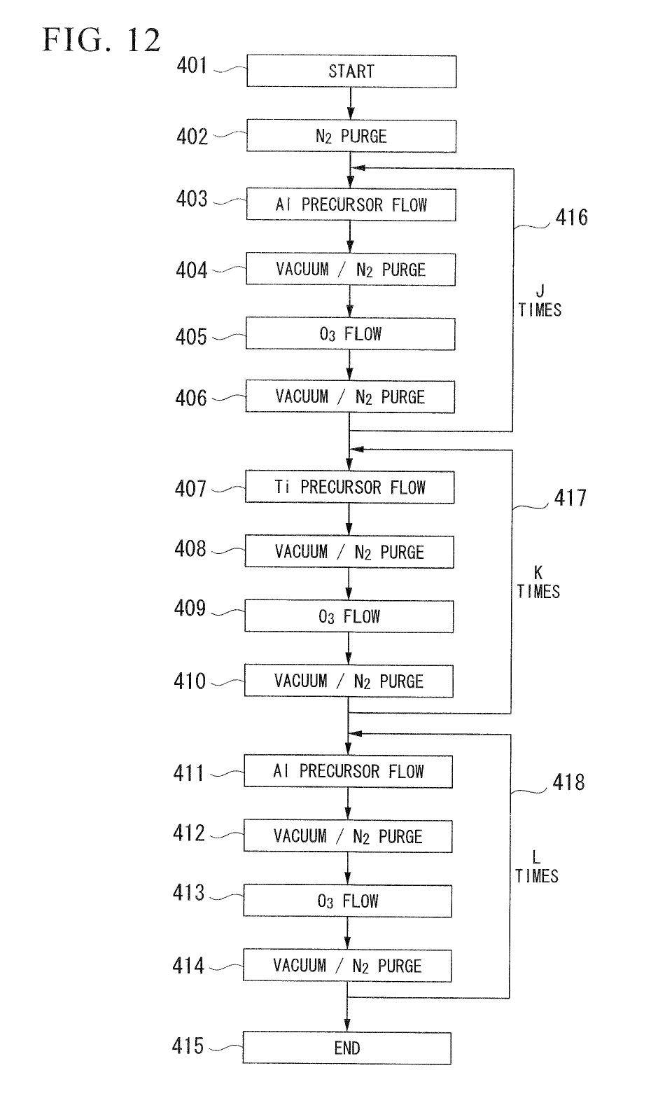

A leakage current density for the each DRAM when a voltage of 1 V is applied is investigated. FIG. 7 shows the leakage current density as a function of the equivalent oxide film thickness (EOT) of the dielectric film.

The EOT at the leakage current density of 1×10⁻⁸ A/cm² (EOT at J=1×10⁻⁸ A/cm²) are further shown in TABLE 1. The leakage current density of 1×10⁻⁸ A/cm² is an upper limit that is requested for the capacitor in the DRAM.

According to the TABLE 1, a value of [A/(A+B)]×100 and a value of [x/(x+y)]×100 are compared. Although there is a tendency that the value of [x/(x+y)]×100 is slightly larger than the value of [A/(A+B)]×100, both values almost coincide. Therefore, it is found that the aluminum composition ratio x and the titanium composition ratio y can be controlled by varying the cycle numbers A and B. Since it is considered that the relationship between the cycle numbers A and B and the composition ratios x and y depend on the constitution of the apparatus, the precursors, the deposition conditions and the like, it is preferred to control the composition ratios x and y by the cycle numbers A and B, based on the relationship between the cycle numbers A and B and the composition ratios x and y, where the relationship is examined for the each condition.

TABLE 1

| | | | | | Al | Effective | EOT (nm) |
|---|---|---|---|---|---|---|---|
| | Electrode | Cycle numbers | | | comp. | dielectric | at J = 10⁻⁸ |
| | materials | A | B | ratio* | (%) | const. k | A/cm² |
| Example 1 | TiN | 1 | 2 | 33 | 35 | ~20 | 1.3 |
| Example 2 | TiN | 1 | 3 | 25 | 27 | ~25 | 1.1 |
| Example 3 | TiN | 1 | 6 | 14 | 15 | ~40 | 0.8 |
| Example 4 | TiN | 1 | 14 | 7 | 7 | ~60 | 1.3 |
| Example 5 | TiN | 0 | 1 | 0 | 0 | ~80 | 1.8 |
| Example 6 | Pt | 1 | 14 | 7 | 7 | ~60 | 0.6 |
| Example 7 | Pt | 0 | 1 | 0 | 0 | ~80 | 0.9 |

ratio* = [A/(A + B)] × 100

Then, according to the EOT at the leakage current density of 1×10⁻⁸ A/cm², when the upper electrode and the under electrode include the titanium nitride film (examples 1 through 5), the EOT becomes thinnest at the aluminum composition of 15%, and the EOT becomes thicker with the aluminum composition departing from 15%. The EOT at the leakage current density of 1×10⁻⁸ A/cm² is preferably thinner than 1.3 nm. When the EOT is thinner than 1.3 nm, the aluminum composition is from 7% to 35%. Therefore, it is found that the appropriate aluminum composition range is 7% to 35%.

However, as is understood from FIG. 7, when the aluminum composition is less than 15% (examples 4 and 5), the leakage current density becomes relative large value for the thick EOT (beyond 1.3 nm). Therefore, when the upper electrode and the under electrode include the titanium nitride film, the aluminum composition of the dielectric film is further preferably set in the range of 15% to 35%.

Then, as shown in FIG. 7, when the upper electrode and the under electrode include the platinum film (example 6), the leakage current density is suppressed compared to that of the same aluminum composition in which the upper electrode and the under electrode include the titanium nitride film. As shown in TABLE 1, the EOTs at the leakage current density of 1×10⁻⁸ A/cm² are 0.9 nm and 0.6 nm for the examples 6 and 7, respectively, since it is considered that a band offset is large for the capacitor in which the upper electrode and the under electrode include the platinum film. That is, when the upper electrode and the under electrode include the platinum film, an EOT less than 1.3 nm can suppress the leakage current density, even if the aluminum composition is in a low composition range (7% through 15%). Furthermore, when the aluminum composition is in the low composition range (7% through 15%), the relative dielectric permittivity becomes high. For this reason, when the upper electrode and the under electrode include the platinum film, there is an advantage for a suppression of the leakage current density and an enhancement of the relative dielectric permittivity.

Alternately, when the upper electrode and the under electrode include the tantalum nitride film, the same tendency for the case of titanium nitride is obtained. On the other hand, when the upper electrode and the under electrode include a ruthenium (Ru) film or an iridium (Ir) film, the same tendency for the case of platinum film is obtained.

According to the present invention, the dielectric film which is provided between the under electrode and the upper electrode, wherein at least a portion of the dielectric film includes the composite oxide film in which a plurality of aluminum oxide films and a plurality of titanium oxide films are provided as perpendicular thereto. In the composite oxide film with this constitution, it is possible to obtain a high relative dielectric permittivity, and, when the equivalent oxide film thickness (EOT) becomes relatively thin, the leakage current can be suppressed. For this reason, the capacitor which includes the composite oxide film makes it possible to obtain a large capacitance even when the minimum processing dimension of the DRAM is decreased to less than 60 nm.

According to the composite oxide film, wherein the aluminum oxide film (relative dielectric permittivity of 9) deposited by the atomic layer deposition method and the titanium oxide film (relative dielectric permittivity of 80) deposited by the atomic layer deposition method alternate and are stacked, the ratio between the cycle number for each process of the aluminum oxide film deposited by the atomic layer deposition method and the cycle number for each process of the titanium oxide film deposited by the atomic layer deposition method is varied so that the aluminum composition ratio x and the titanium composition y can be easily controlled. Therefore, the composite oxide film can provide the desired effective-relative-dielectric-permittivity between those of the aluminum oxide and the titanium oxide (9 through 80).

According to the composite oxide film, wherein the aluminum oxide film deposited by the atomic layer deposition method and the titanium oxide film deposited by the atomic layer deposition method alternate and are stacked, the thermal stability of the titanium oxide film is enhanced so that the high crystallization temperature raises higher than 750° C., due to the effect of aluminum. For this reason, when the annealing process is performed to improve the film quality at approximately 700° C., for example, after the composite oxide film is deposited, the crystallization of the composite oxide film is suppressed so as to maintain the amorphous state. Therefore, enlargement of the leakage current due to the crystallization can be prevented.

Furthermore, according to the dielectric film which includes the composite oxide film, since the precursor having a low vapor pressure such as strontium is not necessary when the dielectric film is formed, it is easy to put a practical application.

According to the application example of the present invention, the DRAM and a consolidation LSI including the DRAM are considered.

Although the invention has been described above in connection with several preferred embodiments thereof, it will be appreciated by those skilled in the art that those embodiments are provided solely for illustrating the invention, and should not be relied upon to construe the appended claims in a limiting sense.

What is claimed is:

1. A capacitor comprising:
an under electrode;
an upper electrode; and
a dielectric film which is provided between said under electrode and said upper electrode, a portion of said dielectric film including a composite oxide film in which a plurality of aluminum oxide films and a plurality of titanium oxide films are provided in a thickness direction thereof.

2. The capacitor as recited in claim 1, wherein said aluminum oxide film and said titanium oxide film are alternately stacked to form said composite oxide film.

3. The capacitor as recited in claim 1, wherein said aluminum oxide film and said titanium oxide film are deposited by an atomic layer deposition method.

4. The capacitor as recited in claim 1, wherein an intermixing of said aluminum oxide film and said titanium oxide film is formed at an interface thereof.

5. The capacitor as recited in claim 1, wherein:
an aluminum composition ratio x and a titanium composition ratio y of said composite oxide film is represented by the composition formula AlₓTi_{y}O_{z}; and
said aluminum composition ratio x and said titanium composition ratio y comply with the equation 7≦[x/(x+y)]×100≦35.

6. The capacitor as recited in claim 5, wherein:
said under electrode and said upper electrode mainly comprise titanium nitride; and
said aluminum composition ratio x and said titanium composition ratio y comply with the equation 15≦[x/(x+y)]×100≦35.

7. The capacitor as recited in claim 5, wherein:
said under electrode and said upper electrode mainly comprise at least one of ruthenium, iridium, platinum, and an alloy thereof; and
said aluminum composition ratio x and said titanium composition ratio y comply with the equation 7≦[x/(x+y)]×100≦15.

8. The capacitor as recited in claim 1, wherein said aluminum oxide film and said titanium oxide film are of an amorphous state.

9. The capacitor as recited in claim 1, wherein said dielectric film further comprises an under aluminum oxide film, said composite oxide film, and an upper aluminum oxide film stacked in sequence on said under electrode.

10. The capacitor as recited in claim 9, wherein said under aluminum oxide film and said upper aluminum oxide film are deposited by the atomic layer deposition method.

11. A method of manufacturing a capacitor that comprises an under electrode, an upper electrode, and a dielectric film provided between said under electrode and said upper electrode, a portion of said dielectric film including a composite oxide film in which a plurality of aluminum oxide films and a plurality of titanium oxide films are stacked, the method comprising, to form said composite oxide film:
depositing said aluminum oxide film; depositing said titanium oxide film; and
alternately repeating the deposition of said aluminum oxide film and said titanium oxide film.

12. The method of manufacturing said capacitor as recited in claim 11, wherein:
depositing said aluminum oxide film comprises
forming an aluminum film on a deposition plane through a chemical reaction of an aluminum precursor gas,
oxidizing said aluminum film into said aluminum oxide film by an oxidization gas, and
alternately repeating forming said aluminum film and oxidizing said aluminum film by a first cycle number; and
depositing said titanium oxide film comprises
forming an titanium film on said deposition plane through a chemical reaction of an titanium precursor gas,
oxidizing said titanium film into said titanium oxide film by said oxidization gas, and
alternately repeating forming said titanium film and oxidizing said titanium film by a second cycle number.

13. The method of manufacturing said capacitor as recited in claim 12, wherein:
an aluminum composition ratio x of said composite oxide film is controlled by said first cycle number; and
a titanium composition ratio y of said composite oxide film is controlled by said second cycle number.

14. The method of manufacturing said capacitor as recited in claim 12, wherein a layer thickness of said composite oxide film is controlled by said first cycle number and said second cycle number.

15. The method of manufacturing said capacitor as recited in claim 13, wherein said aluminum composition ratio x and said titanium composition ratio y are represented by the composition formula AlₓTi_{y}O_{z}, and said aluminum composition ratio x and said titanium composition ratio y comply with the equation 7≦[x/(x+y)]×100≦35.

16. A capacitor manufacturing apparatus for manufacturing a capacitor, said capacitor comprising a dielectric film including a composite oxide film in which a plurality of aluminum oxide films and a plurality of titanium oxide films are stacked by alternately repeating depositing said aluminum oxide film and depositing said titanium oxide film, said capacitor manufacturing apparatus comprising:
a reaction chamber;
a gas supply portion that separately supplies an aluminum precursor gas, a titanium precursor gas and an oxidization gas to said reaction chamber;
a gas exhaust portion that exhausts said gases from said reaction chamber; and
a control portion that controls supply of said gases in said gas supply portion and exhaust of said gases from said gas exhaust portion such that said control portion repeats the atomic layer deposition method by a first cycle number and a second cycle number to obtain a designed aluminum composition ratio x and a designed titanium composition ratio y, based on predetermined relationships between said aluminum composition ratio x and said first cycle number, and between said titanium composition ratio y and said second cycle number.
